(19) United States
(12) Patent Application Publication
(10) Pub. No.: US 2021/0391556 A1
(43) Pub. Date: Dec. 16, 2021

(54) DISPLAY PANEL AND MANUFACTURING METHOD THEREOF

(71) Applicant: Wuhan China Star Optoelectronics Semiconductor Display Technology Co., Ltd., Wuhan (CN)

(72) Inventors: Liying PENG, Wuhan (CN); Fenghao CAI, Wuhan (CN)

(73) Assignee: Wuhan China Star Optoelectronics Semiconductor Display Technology Co., Ltd., Wuhan (CN)

(21) Appl. No.: 16/641,667

(22) PCT Filed: Nov. 19, 2019
(86) PCT No.: PCT/CN2019/119325

§ 371 Date: Feb. 25, 2020

(30) Foreign Application Priority Data
Nov. 11, 2019 (CN) 201911093278.7

(51) Int. Cl. H01L 51/52; H01L 51/56; H01L 51/00

(52) U.S. Cl. CPC H01L 51/5253; H01L 51/0097; H01L 51/56; H01L 51/5259

(57) ABSTRACT

The present disclosure provides a display panel and a manufacturing method thereof. The display panel includes a substrate layer, a first block wall, a first inorganic layer, and an organic layer, wherein the substrate layer includes a display area and a non-display area; the first block wall is disposed in the non-display area of the substrate layer and surrounds the display area. a surface of the first block wall includes a hydrophobic layer; the first inorganic layer covers the substrate layer and exposes the first block wall; the organic layer is disposed on the first inorganic layer and located in the display area.

### FIELD OF INVENTION

The present disclosure relates to the technical field of display, and in particular, relates to a display panel, and a manufacturing method thereof.

### BACKGROUND OF INVENTION

Organic light-emitting diodes (OLEDs) are more sensitive to moisture and oxygen. At present, the commonly used OLEDs-packaging method is thin film packaging, which is that the organic film and the inorganic film are alternately stacked to block moisture and oxygen. The denseness of the inorganic film is better, which can be used to block moisture and oxygen. The organic film can be mainly used to relieve the internal stress of the inorganic film, while also making the packaging layer have a certain flexibility.

However, the organic film layer is usually formed by liquid leveling, and the formed film edge is not easily controlled. When the overflow volume at edges is too much, and the inorganic film layer cannot be covered, moisture and oxygen can infiltrate along the edges of the organic film layer, resulting in package failure.

### SUMMARY OF INVENTION

### Technical Problem

An organic film layer is usually formed by liquid leveling, and the film forming edge is not easily controlled. When the edge overflow volume is too much, and the inorganic film cannot be covered, moisture and oxygen can infiltrate along the edges of the organic film, resulting in package failure.

### Technical Solution

The present disclosure provides a display panel and a manufacturing method thereof, which is able to effectively suppress overflow at edges of an organic layer.

In the first aspect, an embodiment of the present disclosure provides a display panel, and the display panel includes:

a substrate layer including a display area and a non-display area;

a first block wall disposed in the non-display area of the substrate layer and surrounding the display area, wherein a surface of the first block wall includes a hydrophobic layer;

a first inorganic layer covering the substrate layer and exposing the first block wall; and

an organic layer disposed on the first inorganic layer and located in the display area.

In the display panel of the embodiment of the present disclosure, a material of the first block wall is an organic material.

In the display panel of the embodiment of the present disclosure, a material of the hydrophobic layer includes one of a fluorine-containing alkyl vinyl diol, a fluorine-containing alkyl vinyl diol, a fluorine-containing acyl halide or a fluoroalkyl methacrylate.

In the display panel of the embodiment of the present disclosure, the first block wall reacts with fluorine gas through free radical reaction to form the hydrophobic layer.

In the display panel of the embodiment of the present disclosure, the hydrophobic layer is formed by chemical vapor deposition.

In the display panel of the embodiment of the present disclosure, the first block wall is flush with the organic layer.

In the display panel of the embodiment of the present disclosure, the display panel further includes:

a second block wall located between the substrate layer and the first inorganic layer, and the second block wall is arranged around the first block wall.

In the display panel of the embodiment of the present disclosure, a material of the second block wall is an organic material.

In the display panel of the embodiment of the present disclosure, the display panel further includes:

a second inorganic layer covering the first inorganic layer, the first block wall, and the organic layer.

In the display panel of the embodiment of the present disclosure, the substrate layer includes a substrate, a flexible substrate, and an organic light emitting structure which are sequentially disposed on the substrate.

In the second aspect, an embodiment of the present disclosure provides a manufacturing method of a display panel, and the manufacturing method of the display panel includes:

providing a substrate layer, wherein the substrate layer includes a display area and a non-display area;

forming a block wall on the substrate layer surrounding the display area, and performing a hydrophobic treatment on the first block wall;

forming a first inorganic layer on the substrate layer that exposes the first block wall; and

forming an organic layer on the first inorganic layer, wherein the organic layer is located in the display area.

In the manufacturing method of the display panel of the embodiment of the present disclosure, a material of the first block wall is an organic material.

In the manufacturing method of the display panel of the embodiment of the present disclosure, a material of the hydrophobic layer includes one of a fluorine-containing alkyl vinyl diol, a fluorine-containing alkyl vinyl diol, a fluorine-containing acyl halide or a fluoroalkyl methacrylate.

In the manufacturing method of the display panel of the embodiment of the present disclosure, the first block wall reacts with fluorine gas through free radical reaction to form the hydrophobic layer.

In the manufacturing method of the display panel of the embodiment of the present disclosure, the hydrophobic layer is formed by chemical vapor deposition.

In the manufacturing method of the display panel of the embodiment of the present disclosure, the first block wall is flush with the organic layer.

In the manufacturing method of the display panel of the embodiment of the present disclosure, the display panel further includes:

a second block wall located between the substrate layer and the first inorganic layer, and the second block wall is arranged around the first block wall.

In the manufacturing method of the display panel of the embodiment of the present disclosure, a material of the second block wall is an organic material.

In the manufacturing method of the display panel of the embodiment of the present disclosure, the display panel further includes:

a second inorganic layer covering the first inorganic layer, the first block wall, and the organic layer.

In the manufacturing method of the display panel of the embodiment of the present disclosure, the substrate layer includes a substrate, a flexible substrate, and an organic light emitting structure which are sequentially disposed on the substrate.

### Beneficial Effects

The embodiment of the present disclosure provides a display panel including a substrate layer, a first block wall, a first inorganic layer, and an organic layer, wherein the substrate layer includes a display area and a non-display area; the first block wall is disposed in the non-display area of the substrate layer and surrounds the display area; a surface of the first block wall includes a hydrophobic layer; the first inorganic layer covers the substrate layer and exposes the first block wall; the organic layer is disposed on the first inorganic layer and located in the display area. By providing the hydrophobic layer on the first block wall, overflow at edges of the organic layer can be effectively suppressed.

### DESCRIPTION OF DRAWINGS

FIG. 1 is a schematic structural view of a display panel in the prior art.

FIG. 2 is a schematic structural view of a display panel according to an embodiment of the present disclosure.

FIG. 3 is a flow chart of manufacturing method of the display panel according to an embodiment of the present disclosure.

### DETAILED DESCRIPTION OF PREFERRED EMBODIMENTS

In order to more clearly illustrate technical solutions in embodiments of the present disclosure, the drawings used in the description of the embodiments will be briefly introduced below. Obviously, the drawings in the following description are only some embodiments of the present disclosure, but not all the embodiments. Based on the embodiments in the present disclosure, all other embodiments obtained by those skilled in the art without any creative effort fall into the protection scope of the present disclosure.

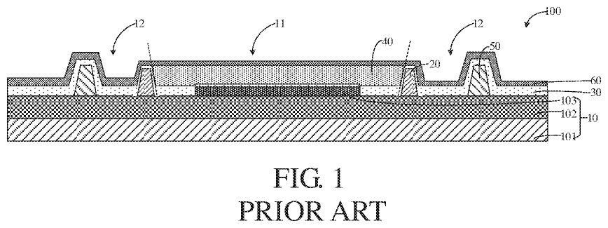

In the prior art, as shown FIG. 1, in order to suppress overflow at edges of an organic layer 40, the structure of a block wall 20 is usually provided on the periphery of a display area 11. However, for making the organic layer 40 have a better leveling effect in the display area 11, a first inorganic layer 30 of the block wall 20 is often beneficial to the expansion of the organic layer 40. Therefore, the arrangement of the block wall 20 still cannot suppress the edge overflow of the organic layer 40 well in the prior art.

For the described above, an embodiment of the present disclosure provides a display panel and a manufacturing method thereof, which is be described in detail below respectively.

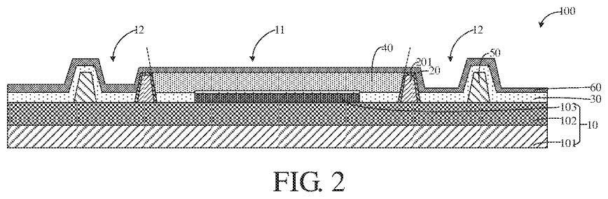

Referring to FIG. 2, a schematic structural view of a display panel according to an embodiment of the present disclosure is illustrated, wherein the display panel 100 includes a substrate layer 10, a first block wall 20, a first inorganic layer 30, and an organic layer 40.

The substrate layer 10 includes a substrate 101, a flexible substrate 102, and an organic light emitting structure 103, which are sequentially disposed on the substrate 101, wherein the substrate 101 is an array substrate for driving the light emitting structure 103 to emit light. The substrate 101 is transparent, translucent, or opaque. The flexible substrate 103 is made of a flexible material, such as polyimide (PI). The flexible substrate 103 is able to increase a bending resistance of the display panel 100. The light emitting structure 103 is able to implement that screen display of the display panel 100. It should be known that the emitting structure 103 is disposed in the display area 11.

The first block wall 20 is disposed in the non-display area 12 of the substrate layer 10. The first block wall 20 disposed around the display area 11 of the substrate layer 10. It should be noted that a surface of the first block wall 10 includes a hydrophobic layer 201.

In some embodiments, a material of the first block wall 20 is an organic material, and the first block wall is able to be subjected to fluorination treatment.

Specifically, fluorine gas could be passed in, so that the first block wall 20 and the fluorine gas react freely to form a hydrophobic layer 201 containing a fluorine ion material on the surface of the first block wall 20. For example, the hydrophobic material is one of a fluorine-containing alkyl vinyl diol, a fluorine-containing alkyl vinyl diol, a fluorine-containing acyl halide, or a fluoroalkyl methacrylate.

In some embodiments, after the first block wall 20 is formed, a fluorine-containing ion material layer is formed by chemical vapor deposition, and then the fluorine-containing ion material layer is etched to form the hydrophobic layer 201.

The first inorganic layer 30 covers the substrate layer 10, and the first inorganic layer 30 exposes the first block wall 30. It should be known that the first inorganic layer 30 covers the light emitting structure 103, and the first inorganic layer is able to protect the light emitting structure 103 to prevent the light emitting structure 103 from being affected by external moisture or oxygen.

A material of the first inorganic layer 30 is made of a material with better hydrophobicity. For example, aluminum oxide (Al₂O₃), aluminum nitride (AlN), aluminum nitride oxide (AlON), silicon carbonitride (SiCN), magnesium oxide (MgO), calcium oxide (CaO), tungsten oxide (WOx), titanium dioxide (TiO₂), titanium nitride (TiNx), titanium nitride (ZrO₂), zirconium nitride (ZrNx), Zinc oxide (ZnO), tantalum pentoxide (Ta₂O₅), hafnium dioxide (HfO₂), hafnium nitride (HfNx), indium trioxide (In₂O₃), cerium oxide (CeOx), or zirconium dioxide (ZrO₂), etc.

The organic layer 40 is disposed on the first inorganic layer 30. The organic layer 40 is located in the display area 11 of the substrate layer 10. It should be known that the first block wall 20 is flush with the organic layer 40. The organic layer 40 mainly functions as a buffer and is used to reduce the stress between the first inorganic layer 30 and a second inorganic layer 60.

It should be known that the first inorganic layer 30 is often beneficial of the expansion of the organic layer 40. Thus, the first inorganic layer 30 is able to be formed on the substrate layer 10 to expose the first block wall 20. At this time, the first block wall 20 including the hydrophobic layer 201 and the organic layer 40 may be directly contacted.

Specifically, the organic layer 40 has certain fluidity, and the first block wall 20 including the hydrophobic layer 201 may limit the organic layer 40 in the display area 11 surrounded by the first block wall 20. The expansion of the organic layer 40 is avoided to increase the width of the non-display area 12.

The first block wall 20 can effectively prevent moisture and oxygen from entering the display panel 100 and prevent the display panel 100 from being corroded by moisture and oxygen.

In some embodiments, the display panel 100 further includes a second block wall 50. The second block wall 50 is disposed between the substrate layer 10 and the first inorganic layer 30 and disposed around the first block wall 20.

Specifically, the second block wall 50 is used to support a mask used for making the inorganic layer 41. If the organic layer 40 overflows the display area 11 surrounded by the first block wall 20 during the process, the second block wall 50 also play a further blocking role to prevent the organic layer 40 from being extended, which is beneficial to the narrow frame of the display panel 100.

In some embodiments, a material of the second block wall 50 may be an organic material. For example, since a silicone material has a small elastic modulus and good bending performance, the display panel 100 is easily cracked during bending, which can improve the bending resistance of the display panel 100. Organosilicon materials contain silicon and oxygen, and have desirable adhesion to inorganic film layers. When the display panel 100 is bent, the inorganic film layer is prevented from being separated from the second block wall 50, and the lateral water blocking ability and bending resistance of the display panel 100 are further enhanced.

In some embodiments, the display panel 100 further includes a second inorganic layer 60, wherein the second inorganic layer 60 covers the first inorganic layer 30, the first block wall 20, and the organic layer 40. The second inorganic layer 60 can effectively prevent moisture or oxygen from entering the display panel 100 and prevent the display panel 100 from being corroded by moisture or oxygen.

A material of the second inorganic layer 60 is made of a material with desirable hydrophobicity. For example, aluminum oxide (Al₂O₃), aluminum nitride (AlN), aluminum nitride oxide (AlON), silicon carbonitride (SiCN), magnesium oxide (MgO), calcium oxide (CaO), tungsten oxide (WOx), titanium dioxide (TiO₂), titanium nitride (TiNx), titanium nitride (ZrO₂), zirconium nitride (ZrNx), Zinc oxide (ZnO), tantalum pentoxide (Ta₂O₅), hafnium dioxide (HfO₂), hafnium nitride (HfNx), indium trioxide (In₂O₃), cerium oxide (CeOx), or zirconium dioxide (ZrO₂), etc.

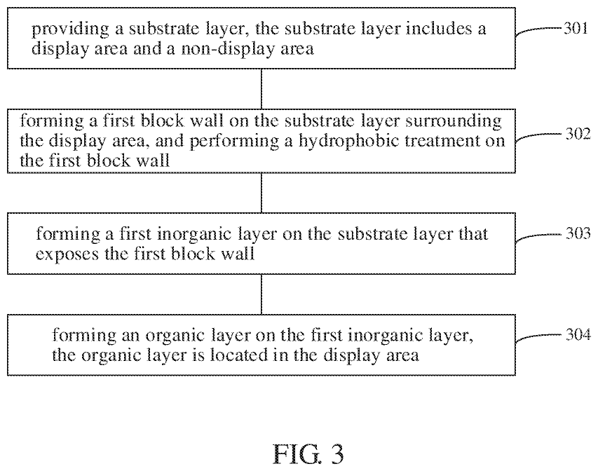

Referring to FIG. 3, a flow chart of a manufacturing method of the display panel according to an embodiment of the present disclosure is illustrate, wherein the specific steps of the manufacturing method of the display panel 100 is as follows:

Step 301, providing a substrate layer 10, wherein the substrate layer 10 includes a display area 11 and a non-display area 12.

Step 302, forming a first block wall 20 on the substrate layer 10 surrounding the display area 11, and performing a hydrophobic treatment on the first block wall 20.

Step 303, forming a first inorganic layer 30 on the substrate layer 10 that exposes the first block wall 20.

Step 304, forming an organic layer 40 on the first inorganic layer 30, wherein the organic layer 40 is located in the display area 11.

In some embodiments, a material of the first block wall 20 is an organic material. The first block wall 20 is fluorinated to form a hydrophobic layer 201 containing a fluorine ion material on a surface of the first block wall 20. For example, a hydrophobic material is one of a fluorine-containing alkyl vinyl diol, a fluorine-containing alkyl vinyl diol, a fluorine-containing acyl halide, or a fluoroalkyl methacrylate.

Specifically, fluorine gas could be passed in, so that the first block wall 20 and the fluorine gas react freely to form a hydrophobic layer 201 containing a fluorine ion material on the surface of the first block wall 20. For example, the hydrophobic material is one of a fluorine-containing alkyl vinyl diol, a fluorine-containing alkyl vinyl diol, a fluorine-containing acyl halide, or a fluoroalkyl methacrylate.

In some embodiments, after the first block wall 20 is formed, a fluorine-containing ion material layer is formed by chemical vapor deposition, and then the fluorine-containing ion material layer is etched to form the hydrophobic layer 201.

As the described above, the embodiment of the present disclosure provides a display panel 100 including a substrate layer 10, a first block wall 20, a first inorganic layer 30, and an organic layer 40, wherein the substrate layer 10 includes a display area 11 and a non-display area 12; the first block wall 20 is disposed in the non-display area of the substrate layer and surrounds the display area; a surface of the first block wall includes a hydrophobic layer; the first inorganic layer covers the substrate layer and exposes the first block wall; the organic layer is disposed on the first inorganic layer and located in the display area. By providing the hydrophobic layer on the first block wall, overflow at edges of the organic layer can be effectively suppressed.

In the above embodiments, the description of each embodiment has its own emphasis. For a part that is not described in detail in one embodiment, reference may be made to related descriptions in other embodiments.

The display panel and the manufacturing method thereof provided in the embodiments of the present disclosure have been described in detail above. Specific embodiments are used herein to explain the principle and implementation of the present disclosure. The descriptions of the above embodiments are only used to help understand the technical solution of the present disclosure and its main ideas. Those of ordinary skill in the art should understand that they can still modify the technical solutions described in the foregoing embodiments, or equivalently replace some of the technical features. These modifications or replacements do not make the essence of the corresponding technical solutions outside the scope of the technical solutions of the embodiments of the present disclosure.

What is claimed is:

1. A display panel, comprising:
a substrate layer including a display area and a non-display area;
a first block wall disposed in the non-display area of the substrate layer and surrounding the display area, wherein a surface of the first block wall includes a hydrophobic layer;
a first inorganic layer covering the substrate layer and exposing the first block wall; and
an organic layer disposed on the first inorganic layer and located in the display area.

2. The display panel according to claim 1, wherein a material of the first block wall is an organic material.

3. The display panel according to claim 2, wherein a material of the hydrophobic layer includes one of a fluorine-containing alkyl vinyl diol, a fluorine-containing alkyl vinyl diol, a fluorine-containing acyl halide, or a fluoroalkyl methacrylate.

4. The display panel according to claim 1, wherein the first block wall reacts with fluorine gas through free radical reaction to form the hydrophobic layer.

5. The display panel according to claim 1, wherein the hydrophobic layer is formed by chemical vapor deposition.

6. The display panel according to claim 1, wherein the first block wall is flush with the organic layer.

7. The display panel according to claim 1, wherein the display panel further includes a second block wall located between the substrate layer and the first inorganic layer, and the second block wall is arranged around the first block wall.

8. The display panel according to claim 1, wherein a material of the second block wall is an organic material.

9. The display panel according to claim 1, wherein the display panel further includes a second inorganic layer covering the first inorganic layer, the first block wall, and the organic layer.

10. The display panel according to claim 1, wherein the substrate layer includes a substrate, a flexible substrate, and an organic light emitting structure which are sequentially disposed on the substrate.

11. A manufacturing method of a display panel, comprising steps of:
providing a substrate layer, wherein the substrate layer includes a display area and a non-display area;
forming a first block wall on the substrate layer surrounding the display area, and performing a hydrophobic treatment on the first block wall;
forming a first inorganic layer on the substrate layer that exposes the first block wall; and
forming an organic layer on the first inorganic layer, wherein the organic layer is located in the display area.

12. The manufacturing method of the display panel according to claim 11, wherein a material of the first block wall is an organic material.

13. The manufacturing method of the display panel according to claim 12, wherein a material of the hydrophobic layer includes one of a fluorine-containing alkyl vinyl diol, a fluorine-containing alkyl vinyl diol, a fluorine-containing acyl halide, or a fluoroalkyl methacrylate.

14. The manufacturing method of the display panel according to claim 11, wherein the first block wall reacts with fluorine gas through free radical reaction to form the hydrophobic layer.

15. The manufacturing method of the display panel according to claim 11, wherein the hydrophobic layer is formed by chemical vapor deposition.

16. The manufacturing method of the display panel according to claim 11, wherein the first block wall is flush with the organic layer.

17. The manufacturing method of the display panel according to claim 11, wherein the display panel further includes a second block wall located between the substrate layer and the first inorganic layer, and the second block wall is arranged around the first block wall.

18. The manufacturing method of the display panel according to claim 17, wherein a material of the second block wall is an organic material.

19. The manufacturing method of the display panel according to claim 11, wherein the display panel further includes a second inorganic layer covering the first inorganic layer, the first block wall, and the organic layer.

20. The manufacturing method of the display panel according to claim 10, wherein the substrate layer includes a substrate, a flexible substrate, and an organic light emitting structure which are sequentially disposed on the substrate.
